(19) United States
(12) Patent Application Publication
(10) Pub. No.: US 2019/0103582 A1
(43) Pub. Date: Apr. 4, 2019

(54) MANUFACTURING METHOD OF FLEXIBLE TRANSPARENT CONDUCTIVE FILM, TRANSPARENT ELECTRODE AND ORGANIC LIGHT-EMITTING DIODE USING FLEXIBLE TRANSPARENT CONDUCTIVE FILM

(71) Applicant: NATIONAL SUN YAT-SEN UNIVERSITY, Kaohsiung City (TW)

(72) Inventors: Mei-Ying Chang, Kaohsiung City (TW); Chun-Chiao Lin, Kaohsiung City (TW); Chieh Kao, Kaohsiung City (TW); Yi-Hao Huang, Kaohsiung City (TW)

(21) Appl. No.: 16/035,854

(22) Filed: Jul. 16, 2018

(30) Foreign Application Priority Data
Sep. 29, 2017 (TW) 106133746

(51) Int. Cl. H01L 51/52; H01L 51/50; H01L 51/00

(52) U.S. Cl. CPC H01L 51/5234; H01L 51/5206; H01L 51/5056; B32B 2307/51; B32B 2307/412; B32B 2307/202; H01L 51/0037

(57) ABSTRACT

A manufacturing method of a flexible transparent conductive film including the steps of mixing a PEDOT:PSS aqueous solution and a polar solvent to obtain a composite solution, then coating and drying the composite solution on a substrate to form the flexible transparent conductive film. By the polar solvent, the method of the present invention can change the arrangement of PEDOT:PSS to enhance the conductivity of PEDOT:PSS significantly so that the flexible transparent conductive film manufactured by the method of the present invention can be used in a transparent electrode of OLED to improve the efficiency of OLED.

### FIELD OF THE INVENTION

This invention relates to a manufacturing method of a flexible transparent conductive film, and more particularly relates to a manufacturing method can significantly enhance conductivity so that the flexible transparent conductive film manufactured by the method can be used as transparent electrode in organic light-emitting diode (OLED).

### BACKGROUND OF THE INVENTION

In commercial OLEDs, transparent conductive films made of indium tin oxide (ITO) are used as anode layers commonly. However, ITO films bended with flexible substrate may be broken to cause electric resistance increment due to the brittle and inflexible characteristics of ITO, and organic layers in OLEDs may be contaminated by released indium ions during decay of ITO to influence the efficiency of OLEDs. Additionally, indium is a rare and expensive metal hence a new and ideal material able to replace ITO is required for OLED research and development.

Poly(3,4-ethylenedioxythiophene):Poly(styrene sulfonic acid) (PEDOT:PSS) is one of potential materials able to replace ITO. PEDOT:PSS is a flexible transparent conductive polymer composed with hydrophobic conductive PEDOT and hydrophilic neutral PSS, and the PSS polymer chain interacts with many PEDOT monomers. PEDOT:PSS polymer has both conductive and flexible characteristics because of charge balance between PEDOT and PSS. However, the conductivity of PEDOT:PSS without post-treatment or modification is approximately 0.3 S/cm and is not sufficient for OLEDs such that conductivity enhancement of PEDOT:PSS is crucial for further applicability.

### SUMMARY

An object of the present invention is to provide a manufacturing method of a flexible transparent conductive film. The method includes the steps of mixing a PEDOT:PSS aqueous solution and a polar solvent to produce a composite solution having 6-10% of the polar solvent in volume; and forming the flexible transparent conductive film by coating and drying the composite solution on a substrate.

Another object of the present invention is to provide a transparent electrode, the transparent electrode includes a flexible transparent conductive film manufactured by the above-mentioned method.

Another object of the present invention is to provide an organic light-emitting diode (OLED), the OLED includes an anode layer, a cathode layer and an organic layer located between the anode layer and the cathode layer. The organic layer includes a hole transporting layer, and the anode layer and/or the hole transporting layer include a flexible transparent conductive film manufactured by the above-mentioned method.

In the present invention, the flexible transparent conductive film is formed by the composite solution having the PEDOT:PSS aqueous solution and the polar solvent, the polar molecules in the polar solvent can insert into PEDOT:PSS to change the chain arrangement of PEDOT:PSS from coil to linear for carrier transportation and conductivity enhancement. Consequently, the flexible transparent conductive film can be used as the transparent electrode to improve efficiency of the OLED significantly.

### DESCRIPTION OF THE DRAWINGS

FIG. 1 is a flowchart illustrating steps of a manufacturing method of a flexible transparent conductive film in accordance with one embodiment of the present invention.

### DETAILED DESCRIPTION OF THE INVENTION

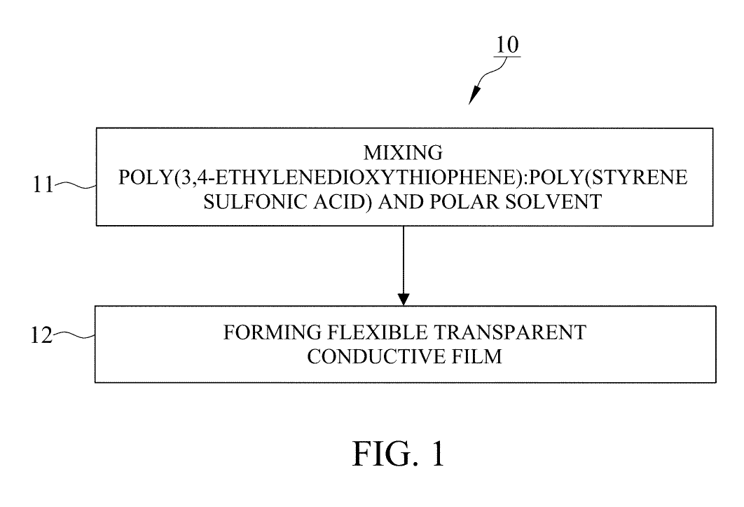

With reference to FIG. 1, a manufacturing method 10 of a flexible transparent conductive film includes a step 11 of mixing PEDOT:PSS aqueous solution and polar solvent, and a step 12 of forming flexible transparent conductive film.

A PEDOT:PSS aqueous solution is prepared firstly. The PEDOT:PSS aqueous solution in this embodiment is Clevios™ PH1000 and the ratio of PEDOT to PSS is 1:2.5. In order to avoid aggregation of PEDOT or PSS, the PEDOT:PSS aqueous solution is preferably shark at a revolution rate of 150-200 rpm for at least 12 hours on a shaker before the step 11 of the manufacturing method 10.

With reference to FIG. 1, the PEDOT:PSS aqueous solution is mixed with a polar solvent in the step 11 to obtain a composite solution. The composite solution contains 6-10% of the polar solvent in volume, and preferably, the composite solution in this embodiment contains approximately 7% of the polar solvent. The polar solvent is an aprotic polar solvent, and further it is, but not limited to, dimethyl sulfoxide (DMSO). PEDOT:PSS doped with DMSO in the step 11 can rearrange from coil structure to linear structure which is beneficial for carrier transportation and conductivity enhancement.

Besides, the composite solution can be shake by a shaker at a revolution rate of 150-200 rpm for at least 12 hours after the step 11. Shaking the composite solution can not only prevent PEDOT or PSS from aggregation but also control PSS ratio in PEDOT:PSS. Polar molecules in the polar solvent may insert to hydrogen bonds between PEDOT and PSS during shaking the composite solution, and the molecule insertion may bring shielding effect to weaken the attraction between PEDOT and PSS such that a part of PSS may separate from PEDOT:PSS to lower PSS ratio in PEDOT:PSS. Owing to PSS ratio relates to conductivity and hydrophilicity of PEDOT:PSS, PEDOT:PSS can't change to linear structure from coil structure easily to enhance conductivity when PSS ratio in PEDOT:PSS is too high, and hydrophilicity of PEDOT:PSS may be decreased when PSS ratio in PEDOT:PSS is too low.

With reference to FIG. 1, after the step 11, a flexible transparent conductive film is formed in the step 12. The composite solution is coated on a substrate and then dried to form the flexible transparent conductive film. The flexible transparent conductive film having multiple layers can be formed on the substrate by repeating the step 12 for different requirements. In this embodiment, the composite solution is shake at 175 rpm for at least 12 hours before coating, and then the composite solution is coated and dried on the substrate at 120° C. for 10 minutes to transform to the flexible transparent conductive film.

The substrate, which is made of glass preferably, is cleaned with neutral detergent, rinsed by deionized (DI) water, acetone and isopropyl alcohol (IPA) successively and dried before coating the composite solution.

The composite solution is coated on the substrate by, but not limited to, spin coating method at a first revolution rate and a second revolution rate successively. The first revolution rate is lower than the second revolution rate.

In this embodiment, the composite solution is dropped on the substrate and spin-coated at about 500 rpm (the first revolution rate) for 5 seconds to disperse on the substrate. Then the composite solution is spin-coated evenly at about 2000 rpm (the second revolution rate) for 30 seconds so can form a flexible transparent conductive film having a substantially even thickness on the substrate and can enhance the film-forming ability and conductivity of the film.

In order to prevent larger particles from damaging the film during spin coating and reducing film-forming ability of the film, the composite solution before dropping on the substrate is preferably filtered by a filter having a pore size of approximately 0.45 μm.

With reference to FIG. 1, the flexible transparent conductive film manufactured by the steps 11 and 12 can be utilized in OLEDs or other optoelectronic elements without post-treatment or modification. For this reason, the manufacturing method 10 of the present invention has advantages of process simplification and cost savings.

For identifying the influence of the manufacturing method 10 of the present invention on the conductivity and transmittance of PEDOT:PSS, four-point probe measurement system and UV/Vis spectrometer are utilized to measure the conductivity and transmittance of the flexible transparent conductive film of the present invention and a reference film respectively. In this measurement, the reference film is a PEDOT:PSS film which is formed by the PEDOT:PSS aqueous solution directly without mixing with the polar solvent.

With reference to table 1, the conductivity of the flexible transparent conductive film and the reference film are 956 S/cm and 0.2 S/cm respectively, and the mean transmittance of the flexible transparent conductive film and the reference film at wavelengths between 400-800 nm (visible region) are 87.6% and 85.5% respectively. The measurement results show the manufacturing method 10 of the present invention can significantly enhance the film conductivity and maintain the film transmittance of PEDOT:PSS (higher than 80%), and the flexible transparent conductive film manufactured by the method 10 can satisfy requirements of OLEDs.

TABLE 1

| | | Mean | |
|---|---|---|---|
| | Conductivity | Transmittance | PSS/PEDOT |
| Flexible Transparent | 956 S/cm | 87.6% | 2.13 |
| Conductive Film | | | |
| Reference Film | 0.2 S/cm | 85.5% | 2.55 |

With reference to table 1, in order to measure the ratio of PSS to PEDOT after mixing with the polar solvent, surface analyses of the flexible transparent conductive film of the present invention and the reference film are studied by X-ray photoelectron spectrometer (XPS). The bonding energy measured in XPS analysis is between 162 eV and 172 eV, and the peaks at approximately 164 eV and 168 eV are S₂P signals of PEDOT and PSS, respectively. According to the results of XPS analysis, the ratio of PSS to PEDOT is 2.13:1 (PSS/PEDOT=2.13) on the surface of the flexible transparent conductive film of the present invention, and the ratio of PSS to PEDOT is 2.55:1 (PSS/PEDOT=2.55) on the surface of the reference film. This study reveals the fact that the manufacturing method 10 of the present invention can reduce PSS ratio in PEDOT:PSS such that PEDOT:PSS can transform to linear structure which is better for carrier transportation and can enhance the conductivity of the flexible transparent conductive film significantly.

The flexible transparent conductive film manufactured by the method 10 of the present invention can be utilized in a transparent electrode and OLED. The OLED includes an anode layer, a cathode layer and an organic layer. The organic layer is located between the anode layer and the cathode layer and includes a hole transporting layer. And the anode layer and/or the organic layer include the flexible transparent conductive layer manufactured by the method 10 of the present invention. The excellent conductivity of the flexible transparent conductive film can improve the efficiency of the OLED.

With reference to table 2, the flexible transparent conductive film of the present invention and a ITO film are respectively involved in the anode layer of the OLED to study the influence of the films on the luminance efficiency of the OLED. This study compares the peak brightness, current efficiency, power efficiency and external quantum efficiency (EQE) at 1000 cd/m² luminance level of the films. The luminance efficiency of the OLED having the flexible transparent conductive film is not higher than but close to that of the OLED having the ITO film. As a result, the flexible transparent conductive film of the present invention is more appropriate to the flexible substrate in the OLED because of excellent conductivity and flexibility.

TABLE 2

| | | 1000 cd/m² Luminance Level | | |
|---|---|---|---|---|
| | Peak | Current | Power | |
| | Brightness | Efficiency | Efficiency | EQE |
| Flexible Transparent | 9865 cd/m² | 18.5 cd/A | 6.9 lm/W | 9.1% |
| Conductive Film | | | | |
| ITO Film | 22910 cd/m² | 28.6 cd/A | 12.3 lm/W | 13.0% |

While this invention has been particularly illustrated and described in detail with respect to the preferred embodiments thereof, it will be clearly understood by those skilled in the art that is not limited to the specific features shown and described and various modified and changed in form and details may be made without departing from the spirit and scope of this invention.

What is claimed is:

1. A manufacturing method of flexible transparent conductive film, comprising:
mixing a poly(3,4-ethylenedioxythiophene):poly(styrene sulfonic acid) aqueous solution and a polar solvent, a composite solution having 6-10% of the polar solvent in volume is obtained; and
forming a flexible transparent conductive film, the composite solution is coated and dried on a substrate to form the flexible transparent conductive film.

2. The manufacturing method in accordance with claim 1, wherein the polar solvent is dimethyl sulfoxide.

3. The manufacturing method in accordance with claim 1, wherein the composite solution contains approximately 7% of the polar solvent.

4. The manufacturing method in accordance with claim 2, wherein the composite solution contains approximately 7% of the polar solvent.

5. The manufacturing method in accordance with claim 1, wherein the composite solution is coated on the substrate by a spin coating method.

6. The manufacturing method in accordance with claim 5, wherein the composite solution is coated on the substrate at a first revolution rate and a second revolution rate successively, and the first revolution rate is lower than the second revolution rate.

7. The manufacturing method in accordance with claim 6, wherein the first revolution rate is approximately 500 rpm, and the second revolution rate is approximately 2000 rpm.

8. The manufacturing method in accordance with claim 1, wherein the composite solution is dried at approximately 120° C. for approximately 10 minutes.

9. The manufacturing method in accordance with claim 1, wherein the composite solution is shake at a revolution rate of 150-200 rpm for at least 12 hours before coating the composite solution on the substrate.

10. A transparent electrode comprising a flexible transparent conductive film manufactured by the method in accordance with claim 1.

11. An organic light-emitting diode comprising an anode layer, a cathode layer and an organic layer, wherein the organic layer is located between the anode layer and the cathode layer and includes a hole transporting layer, and wherein the anode layer and/or the organic layer include a flexible transparent conductive film manufactured by the method in accordance with claim 1.
